(19) United States
(12) Patent Application Publication
(10) Pub. No.: US 2025/0173960 A1
(43) Pub. Date: May 29, 2025

(54) AUTOMATIC CALCULATION DEVICE AND AUTOMATIC CALCULATION PROGRAM

(71) Applicant: SANEI CO., LTD., Hiroshima (JP)

(72) Inventor: Makoto YAMAMOTO, Hiroshima (JP)

(73) Assignee: SANEI CO., LTD., Hiroshima (JP)

(21) Appl. No.: 18/894,529

(22) Filed: Sep. 24, 2024

(30) Foreign Application Priority Data
Nov. 28, 2023 (JP) 2023-200647

(51) Int. Cl. G06T 17/00

(52) U.S. Cl. CPC G06T 17/00

(57) ABSTRACT

An object is to enable accurate grasp of rainwater runoff in a short time. An automatic calculation device includes: a three-dimensional model obtaining unit configured to obtain a three-dimensional model; a calculation unit configured to calculate a highest point and a lowest point based on the three-dimensional model; an area generation unit configured to generate multiple areas by automatically dividing a rainwater catchment area in the three-dimensional model in a range from the highest point to the lowest point calculated by the calculation unit, based on design information owned by a user; and an output unit configured to calculate an area of each of the areas generated by the area generation unit and output the area obtained by the calculation, and calculate and output rainwater runoff by using the area obtained by the calculation.

### CROSS-REFERENCE TO RELATED APPLICATION

This application claims priority to Japanese Patent Application No. 2023-200647 filed on Nov. 28, 2023, the entire disclosure of which is incorporated by reference herein.

### BACKGROUND

The present disclosure relates to an automatic calculation device and an automatic calculation program for use, for example, in designing of roads, house pads, residential land development, rivers, parking lots, harbor facilities, and the like.

For example, Japanese Unexamined Patent Publication No. 2001-125949 discloses a road planning and designing support system that performs planning and designing of roads and their surroundings based on current topographical data and generates various drawing data. As current three-dimensional data representing the current topography and a planning model, the road planning and designing support system of Japanese Unexamined Patent Publication No. 2001-125949 is configured to obtain contour data, generate three-dimensional mesh data based on the contour data obtained, and then generate bird's-eye view data based on the three-dimensional mesh data generated.

### SUMMARY

The existing two-dimensional design of roads, house pads, residential land development, rivers, parking lots, harbor facilities, and the like requires a considerable amount of effort to determine which part is higher or lower in height, based on the gradient information such as a gradient and a cross slope. When both the gradient and the cross slope are intricately combined, the direction of the gradient is often mistaken.

Especially in Japan with a lot of rainfall, the design of irrigation and drainage system is very important, and it is highly desirable to calculate rainwater runoff without making any mistakes.

In view of the foregoing points, an object of the present disclosure is to enable accurate grasp of rainwater runoff in a short time.

In order to achieve the object, an aspect of the present disclosure is directed to an automatic calculation device configured to automatically calculate rainwater runoff of a predetermined area on a three-dimensional model representing a current topography and a planning model. The automatic calculation device includes: a three-dimensional model obtaining unit configured to obtain the three-dimensional model; a calculation unit configured to calculate a highest point and a lowest point based on the three-dimensional model obtained by the three-dimensional model obtaining unit; an area generation unit configured to generate multiple areas by automatically dividing a rainwater catchment area in the three-dimensional model in a range from the highest point to the lowest point calculated by the calculation unit, based on design information owned by a user; and an output unit configured to calculate an area of each of the areas generated by the area generation unit and output the area obtained by the calculation, and calculate and output rainwater runoff by using the area obtained by the calculation.

According to this configuration, the three-dimensional model obtaining unit obtains a three-dimensional model representing the current topography and a planning model. Since the three-dimensional model obtained includes height information, the calculation unit calculates the highest point and the lowest point on the three-dimensional model based on the height information of the three-dimensional model. The height information includes contour lines. The highest point and the lowest point on the three-dimensional model may be calculated based on the contour lines.

It is also possible to calculate, output, and display a path extension and a gradient between the highest point and the lowest point.

The area generation unit generates multiple areas by automatically dividing, for example, the rainwater catchment area in the three-dimensional model in a range from the highest point to the lowest point, based on the design information owned by the user. The output unit calculates the area of each of the multiple areas generated by the above process. It becomes possible to calculate rainwater runoff by using the area obtained through the calculation. This allows the user to grasp accurately the rainwater runoff of each area by simply entering the three-dimensional model, design information, or the like.

Further, the design information may include any one or more of information on an existing flow end, information on a boundary between cut and embankment, and information on a longitudinal drainage.

The calculation unit can calculate the highest point and the lowest point based on a combined gradient consisting of a gradient in a longitudinal direction and a gradient in a lateral direction.

The area generation unit can generate the multiple areas by dividing the rainwater catchment area in the three-dimensional model in a lateral direction of a roadway according to a predetermined attribute.

The automatic calculation device may include a display configured to display the areas generated by the area generation unit and the area output from the output unit. It is thus possible to display the catchment area in the form that allows the user to grasp the catchment area of each area.

The display can show the rainwater runoff output from the output unit. It is thus possible to grasp the rainwater runoff of each area.

The output unit can calculate a highest point and a lowest point of each of the areas and generates and outputs high/low information indicating a relatively lower part of the area based on the highest point and the lowest point of each of the areas. In this case, the display can show an arrow based on the high/low information output from the output unit, along with the three-dimensional model. The display can show a high/low indication indicating a relatively lower part based on the high/low information output from the output unit, along with the three-dimensional model.

It is thus possible to show accurate high/low indication based on the highest point and the lowest point calculated by the output unit, without a need for the user (the design engineer) to obtain the direction of the gradient of each area. The design engineer can obtain the accurate flow direction easily and accurately by viewing the display.

Another aspect of the present disclosure is directed to an automatic calculation program for catchment area, the program being configured to automatically calculate a catchment area of a predetermined area on a three-dimensional model representing a current topography and a planning model. The automatic calculation program can cause a computer to execute: a three-dimensional model obtaining step of obtaining the three-dimensional model; a calculation step of calculating a highest point and a lowest point based on the three-dimensional model obtained in the three-dimensional model obtaining step; an area generation step of generating multiple areas by automatically dividing a rainwater catchment area in the three-dimensional model in a range from the highest point to the lowest point calculated in the calculation step, based on design information owned by a user; and an output step of calculating an area of each of the areas generated in the area generation step and outputting the area obtained by the calculation, and calculating and outputting rainwater runoff by using the area obtained by the calculation.

Yet another aspect of the present disclosure is directed to an automatic calculation method for catchment area, the method automatically calculating a catchment area of a predetermined area on a three-dimensional model representing a current topography and a planning model. The automatic calculation method includes: a three-dimensional model obtaining step of obtaining the three-dimensional model; a calculation step of calculating a highest point and a lowest point based on the three-dimensional model obtained in the three-dimensional model obtaining step; an area generation step of generating multiple areas by automatically dividing a rainwater catchment area in the three-dimensional model in a range from the highest point to the lowest point calculated in the calculation step, based on design information owned by a user; and an output step of calculating an area of each of the areas generated in the area generation step and outputting the area obtained by the calculation, and calculating and outputting rainwater runoff by using the area obtained by the calculation.

As described above, a region from a highest point to a lowest point calculated based on a three-dimensional model can be divided automatically to generate multiple areas based on design information owned by a user, and rainwater runoff can be calculated and output using the area of each area generated. Accordingly, the user can grasp the catchment area accurately and quickly.

### BRIEF DESCRIPTION OF THE DRAWINGS

FIG. 1 is a configuration diagram of an automatic calculation device for catchment area according to an embodiment of the present invention.

FIG. 2 is a block diagram of the automatic calculation device for catchment area.

FIG. 3 is a flowchart showing an example procedure of the automatic calculation of the catchment area.

FIG. 4 is a diagram illustrating an example three-dimensional display mode.

FIG. 5 is a diagram illustrating an example planar display mode.

FIG. 6 is a diagram illustrating an example three-dimensional polygonal display mode.

FIG. 7 is a diagram illustrating an example enlarged display in a three-dimensional polygonal display mode.

FIG. 8 is a diagram for explaining a case in which a highest point and a lowest point exist in the longitudinal direction.

FIGS. 9A to 9F are diagrams for explaining a case in which a highest point and a lowest point exist in the lateral direction.

FIG. 10 is a diagram illustrating an example in which design information is displayed.

FIG. 11 is a diagram illustrating an example in which the drainage area is divided into areas.

FIG. 12 is a diagram illustrating an example in which dividing lines are displayed.

FIG. 13 is a diagram illustrating an example display of the area numbers, catchment areas, and runoff amounts.

FIG. 14 is a diagram illustrating an example display of a flow direction.

FIG. 15 is a flowchart showing an example processing procedure when there is no design information.

FIG. 16 is a diagram illustrating an example display of contour lines.

FIG. 17 is a diagram illustrating an example of a planned three-dimensional model for a housing site, a developed site, a parking lot, or the like.

FIG. 18 is a diagram illustrating a case in which contour lines are superimposed on a planned three-dimensional model.

FIG. 19 is a diagram illustrating a case in which a ridge line or a valley line is superimposed on a planned three-dimensional model.

FIG. 20 is a diagram for explaining an example of an area division.

FIG. 21 is a diagram illustrating a case in which the catchment area and the runoff amount are displayed on a planned three-dimensional model.

FIG. 22 is a diagram illustrating a case in which a flow direction is displayed on the planned three-dimensional model.

### DETAILED DESCRIPTION

Embodiments of the present invention will be described in detail below with reference to the drawings. It should be noted that the following description of preferred embodiments is merely exemplary in nature and does not intend to limit the present invention or applications or use thereof.

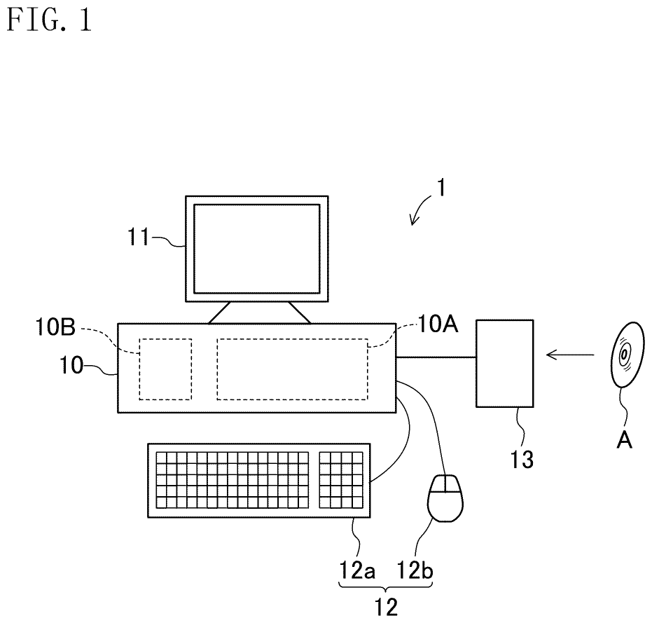

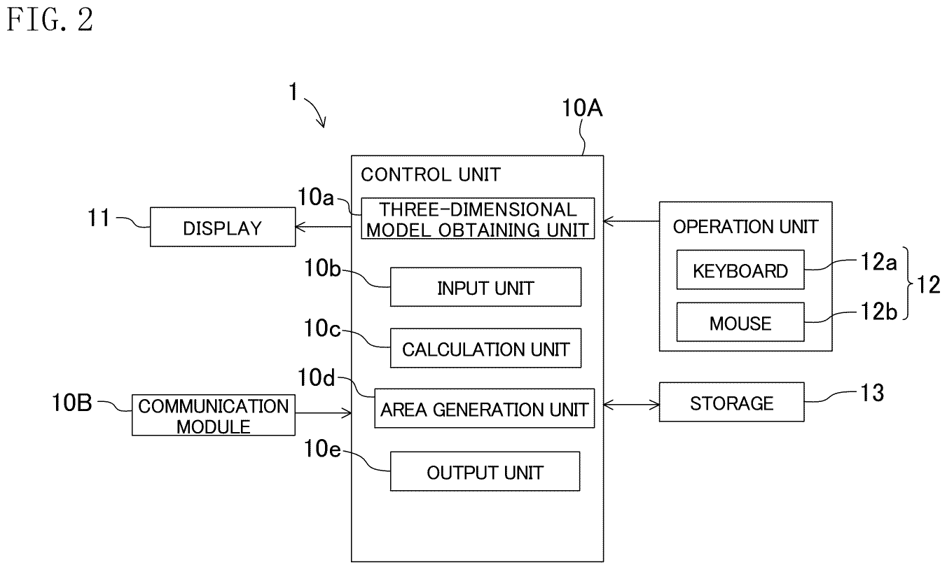

FIG. 1 is a diagram illustrating a configuration of an automatic calculation device 1 of an embodiment of the present invention, and FIG. 2 is a block diagram of the automatic calculation device 1. The automatic calculation device 1 automatically calculates rainwater runoff in a predetermined area on a three-dimensional model representing a current topography and a planning model, and can be configured by a general-purpose personal computer or a dedicated computer, for example.

The automatic calculation device 1 includes a body 10, a display 11, an operation unit 12, and a storage 13. The body 10 includes a control unit 10A and a communication module 10B. The control unit 10A includes, for example, a central processing unit (CPU), and a ROM and a RAM (memory) and operates according to a program. The memory is a work memory that carries out an automatic calculation program according to the embodiment of the present invention when the CPU executes the automatic calculation program, or a buffer memory that stores data temporarily. The automatic calculation program is a program that automatically calculates the rainwater runoff in a predetermined area on a three-dimensional model representing the current topography and a planning model, and causes the computer to perform multiple steps to calculate the rainwater runoff, which will be described in detail later.

The communication module 10B communicates with external terminals via, for example, the Internet, and is configured to transmit and receive data. The communication module 10B may be provided as needed.

As illustrated in FIG. 2, the control unit 10A includes a three-dimensional model obtaining unit 10a, an input unit 10b, a calculation unit 10c, an area generation unit 10d, an output unit 10e, and the like, which will be described below. The three-dimensional model obtaining unit 10a, the input unit 10b, the calculation unit 10c, the area generation unit 10d, and the output unit 10e may be implemented by the hardware constituting the control unit 10A alone or a combination of hardware and software. For example, when the CPU runs the automatic calculation program, the control unit 10A can implement the functions of the three-dimensional model obtaining unit 10a, the input unit 10b, the calculation unit 10c, the area generation unit 10d, and the output unit 10e.

The display 11 is implemented, for example, by a liquid crystal display device or an organic EL display device. The display 11 is connected to the output unit 10e of the control unit 10A, controlled by the output unit 10e, and capable of displaying screens, such as various types of setting screens, an input screen, a design screen, an analysis screen, and an output screen.

The operation unit 12 is implemented by a device handled by the user to operate the automatic calculation device 1. The operation unit 12 includes, for example, a keyboard 12a and a mouse 12b, and may also include a touch screen incorporated in the display 11 or various types of pointing devices. The operation unit 12 is connected to the control unit 10A so that a user's operation on the operation unit 12 can be detected by the control unit 10A.

The storage 13 is implemented, for example, by a hard disk drive or a solid-state drive capable of storing various data and programs. The storage 13 is connected to the control unit 10A and stores transmitted data and reads the stored data in accordance with an instruction from the control unit 10A. The storage 13 may be incorporated in the body 10 or may be provided outside the body 10. The storage 13 may be an external server or a so-called cloud storage system. Only part of the storage 13 may be incorporated in the body 10, and the other may be provided outside.

The storage 13 stores an automatic calculation program that causes a computer to execute the steps described later. The automatic calculation program may be provided to the user in any format. For example, as illustrated in FIG. 1, the user may be provided with a recording medium A, such as a CD-ROM or a DVD-ROM storing the program, or may download the program from an external server via the Internet. When a flow direction display program that has been provided is installed in a general-purpose personal computer or the like, the personal computer or the like can be used as the automatic calculation device 1.

Installation of the automatic calculation program in the general-purpose personal computer or the like may be achieved by installing the program in the storage 13. When the general-purpose personal computer or the like makes access to the external server in which the automatic calculation program is installed, the personal computer or the like can also be used as the automatic calculation device 1. The automatic calculation program can be installed in any location.

The automatic calculation device 1 automatically calculates and provides the user with rainwater runoff in a predetermined area on a three-dimensional model representing various current topographies and planning models such as roads, house pads, residential land development, rivers, parking lots, harbor facilities, and the like, and enables visual check of the direction and amount of water flow in the area. In determining the rainwater runoff (runoff amount Q), the automatic calculation device 1 calculates, for example, the highest point and the lowest point of a road surface, a slope, a flat region, etc., and automatically divides the three-dimensional model based on design information owned by the user. The automatic calculation device 1 then calculates the area of each of the divided areas and presents the obtained area and the rainwater runoff to the user in a displayable format. The automatic calculation device 1 can further indicate the direction of water flow for each of the divided areas with an arrow, for example.

Further, the automatic calculation program is a program that can automatically calculate the rainwater runoff in a predetermined area on a three-dimensional model representing the current topography and a planning model by causing the computer to operate as follows. It is possible to practice a method of automatically calculating the rainwater runoff in a predetermined area on a three-dimensional model representing the current topography and a planning model, by using the automatic calculation device 1.

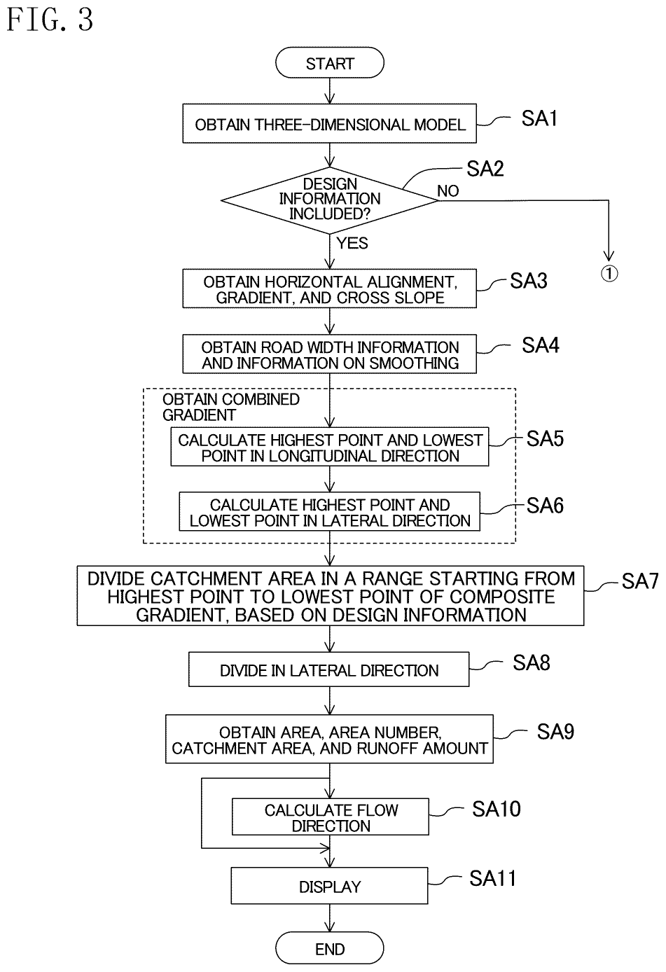

The configuration of each unit of the automatic calculation device 1 will be described below with reference to the flowcharts in FIG. 1, FIG. 2, and FIG. 3. The three-dimensional model obtaining unit 10a illustrated in FIG. 2 obtains a three-dimensional model representing the current topography and a planning model, and the three-dimensional model may include a road model. The input unit 10b receives, for example, an input of a setting value or design information input by the user. The calculation unit 10c calculates a highest point and a lowest point on the three-dimensional model, based on the three-dimensional model obtained by the three-dimensional model obtaining unit 10a. The area generation unit 10d generates multiple areas by automatically dividing the rainwater catchment area in the three-dimensional model in a range from the highest point to the lowest point calculated by the calculation unit 10c, based on the design information owned by the user. Thus, the area of the rainwater catchment area is divided.

The calculation unit 10c can calculate, and output, the path extension between the highest point and the lowest point as well as the gradient between the highest point and the lowest point. The path extension between the highest point and the lowest point and the gradient between the highest point and lowest point output from the calculation unit 10c are displayed on the display 11.

The output unit 10e calculates the size of each of the areas generated by the area generation unit 10d and outputs the area obtained through the calculation, and calculates and outputs the rainwater runoff using the area obtained through the calculation.

The three-dimensional model obtainable by the three-dimensional model obtaining unit 10a is stored in, for example, a storage 13, an external server, or a recording medium such as a CD-ROM or DVD-ROM (hereinafter collectively referred to as storage 13 or the like) as data in any given format. The user of the automatic calculation device 1 operates the operation unit 12 to read the desired three-dimensional model data from the storage 13 or the like, so that the three-dimensional model obtaining unit 10a obtains the three-dimensional model. If multiple three-dimensional model data are stored in the storage 13 or the like, the user may use operation unit 12 to select, and then read, the desired three-dimensional model data. The step of obtaining a three-dimensional model is referred to as a three-dimensional model obtaining step, which is performed in step SA1 of the flowchart in FIG. 3.

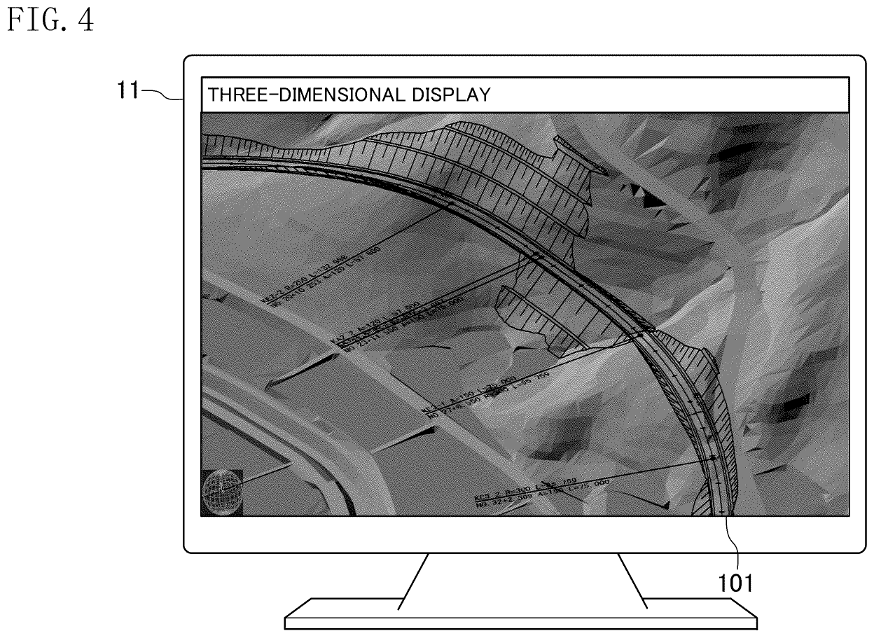

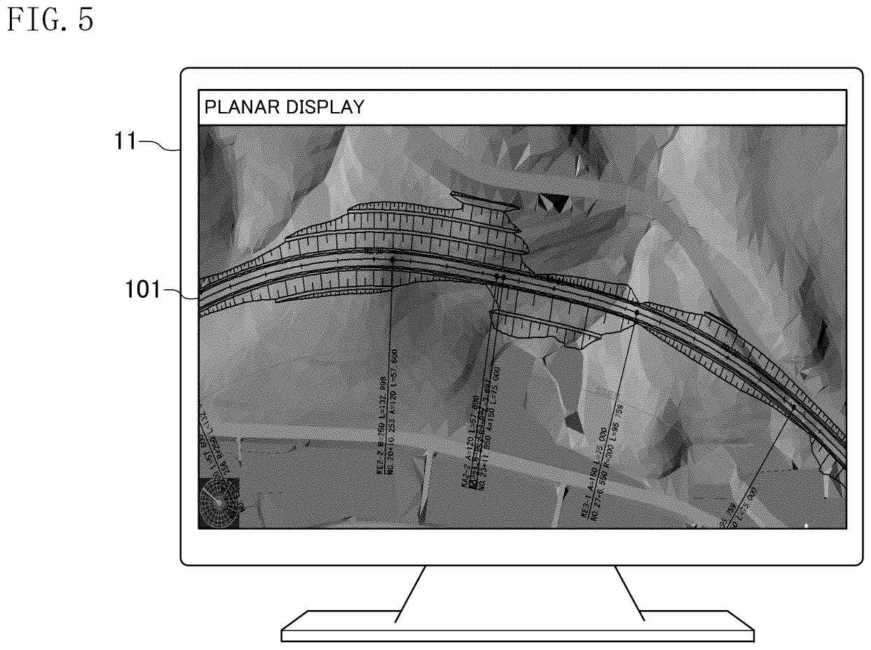

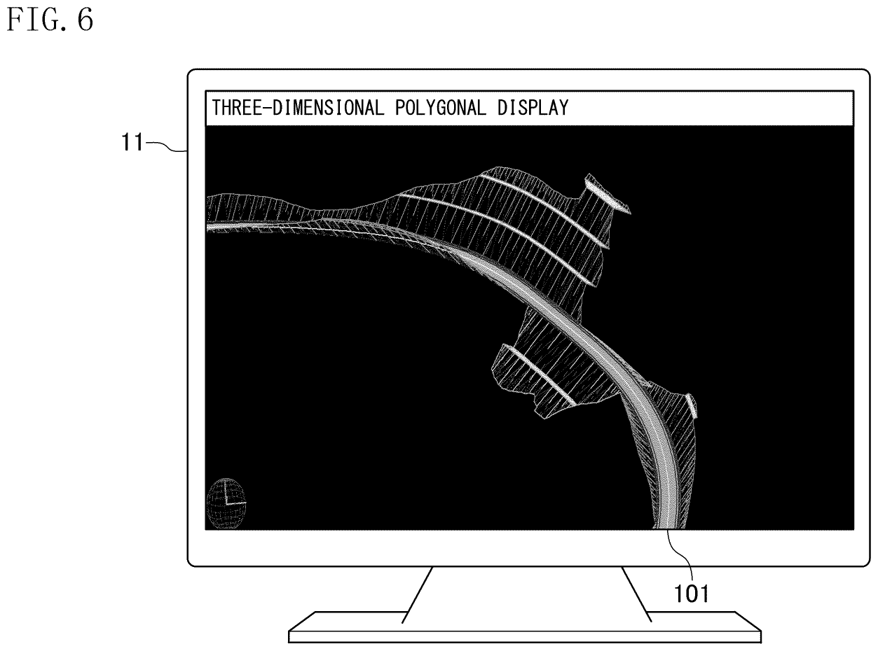

The three-dimensional model data obtained in step SA1 is temporarily stored inside the automatic calculation device 1. The output unit 10e illustrated in FIG. 2 reads the temporarily stored three-dimensional model data, converts the same into the three-dimensional display mode in FIG. 4, the planar display mode illustrated in FIG. 5, and the three-dimensional polygonal display mode illustrated in FIG. 6, and shows them on the display 11. The user can select whether to display the image in the three-dimensional display mode, the planar display mode, or the three-dimensional polygonal display mode by operating the operation unit 12. In FIG. 4 to FIG. 6, the reference character 101 indicates a road.

When the three-dimensional display mode is selected by the user, the output unit 10e illustrated in FIG. 2 controls the display 11 to display the three-dimensional model in the three-dimensional display mode illustrated in FIG. 4, so the user can grasp the topography in three dimensions. When the planar display mode is selected by the user, the output unit 10e controls the display 11 to display the three-dimensional model in the planar display mode illustrated in FIG. 5, so the user can grasp the topography in planar view. When the three-dimensional polygonal display mode is selected by the user, the output unit 10e controls the display 11 to display the three-dimensional model in the three-dimensional polygonal display mode illustrated in FIG. 6, so the user can grasp the topography as a collection of three-dimensional polygons. The process of displaying the three-dimensional model on the display 11 is referred to as a three-dimensional model display step.

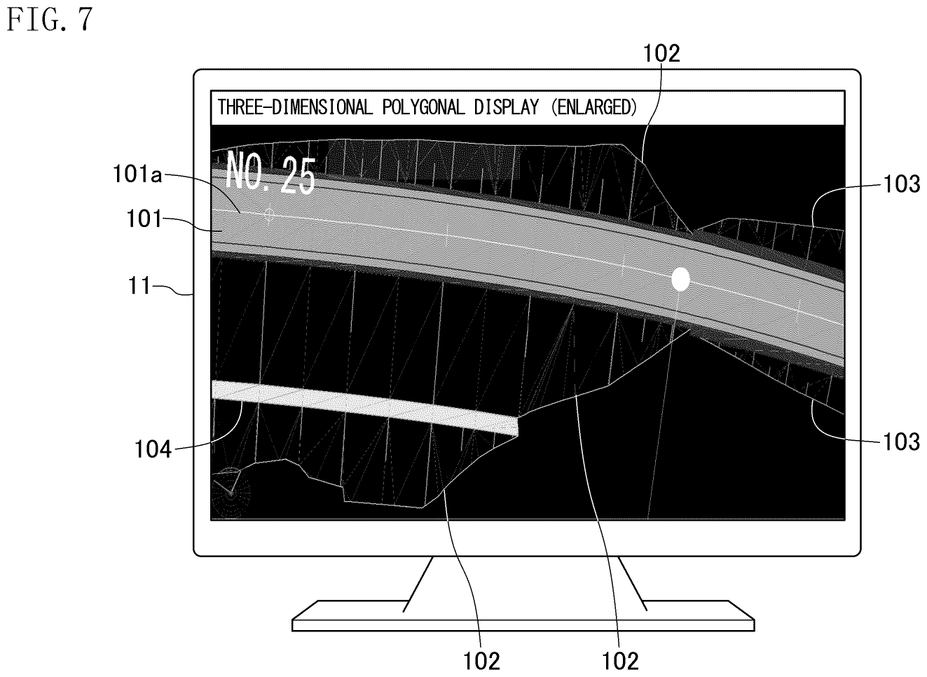

In the three-dimensional model display step, a part of the three-dimensional model displayed on the display 11 can be enlarged. For example, as illustrated in FIG. 7, the three-dimensional data shown in the three-dimensional polygonal display mode can be enlarged to check in detail. By operating the operation unit 12, the user can select a part to be enlarged and its magnification rate. Any part can be enlarged at any magnification rate. It is also possible to reduce the size after the enlargement. The three-dimensional model can also be displayed on the display 11 in a scrollable manner.

As illustrated in FIG. 7, a road 101 has a road center alignment 101a. In this example, there is an embankment 102 and a cut 103 on both sides of the road 101. There is a berm 104 between the embankments 102 below the road 101 in FIG. 7. Although the embankments 102, the cuts 103, and the berm 104 can be grasped on the three-dimensional model in this manner, it is difficult to grasp the direction and degree of the gradient of each part accurately not only on the two-dimensional plan drawing, but also on the three-dimensional model as well. In particular, there is a risk of incorrectly grasping the gradient at points where both gradient (gradient in the longitudinal direction) and cross slope (gradient in the lateral direction) are intricately combined. The present embodiment allows the user to accurately grasp the rainwater runoff and flow direction, even on the three-dimensional model such as one illustrated in FIG. 7, through the following steps. Here, the longitudinal direction is along the centerline of the road, and the lateral direction is orthogonal to the centerline of the road.

In step SA2 of the flowchart illustrated in FIG. 3, the three-dimensional model obtaining unit 10a determines whether the three-dimensional model obtained in step SA1 has design information. The design information includes, for example, any one or more of the following: height information at each point on a ground surface, road center alignment (horizontal alignment) information, gradient information, cross slope information, road width information, information on smoothing, information on an existing flow end, information on a boundary between cut and embankment, information on a longitudinal drainage, information on adjacent land, information on a nearby river, information on a sewer line, information on an existing catchment basin, and the like. The existing flow end is an end of a flow path that has already been installed. The boundary between cut and embankment is the boundary between a cut and an embankment. The longitudinal drainage is a drainage channel that extends longitudinally along a slope.

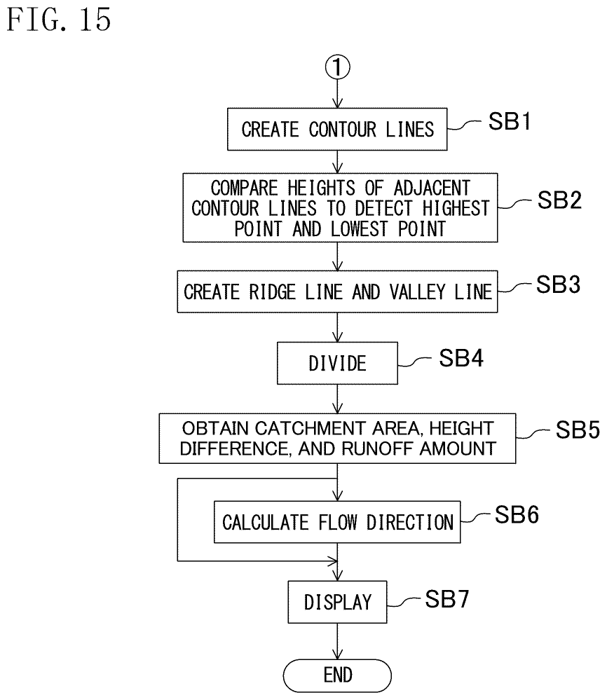

If the determination in step SA2 is YES, and the three-dimensional model includes the design information, the process proceeds to step SA3. If the determination in step SA2 is NO, and the three-dimensional model does not include the design information, the process proceeds to another flowchart (see FIG. 15) described later.

In step SA3, the calculation unit 10c obtains the horizontal alignment, the gradient, and the cross slope from among the design information. This way, the height of each point in the three-dimensional model can be obtained. In step SA4, the calculation unit 10c obtains the road width information and the information on smoothing from among the design information. This way, information on the road can be obtained.

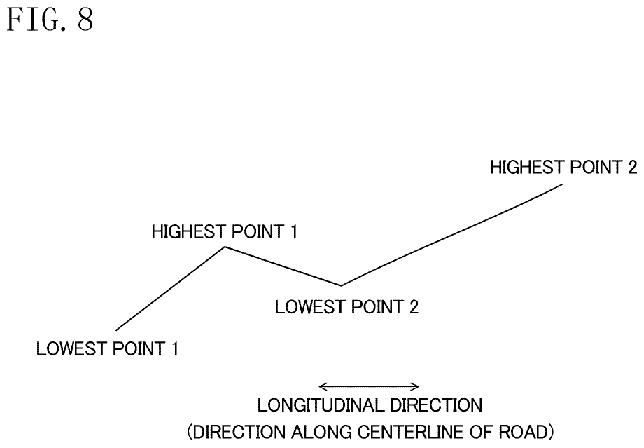

Then, in steps SA5 and SA6, the calculation unit 10c calculates and obtains a combined gradient consisting of the gradient in the longitudinal direction and the gradient in the lateral direction. For example, as illustrated in FIG. 8, there may be a highest point 1, a highest point 2 and so on that can be the highest points in the longitudinal direction. There may also be a lowest point 1, a lowest point 2 and so on that can be the lowest points in the longitudinal direction as a pair with a corresponding one of the highest points.

When calculating the highest point and the lowest point in the longitudinal direction of the three-dimensional model, the height information of each point is calculated from the multiple pieces of information obtained in steps SA3 and SA4. Based on this height information calculated, it is possible to calculate a highest point position and a lowest point position (measurement points). Steps SA5 and SA6 are calculation steps to calculate the highest point and the lowest point based on the three-dimensional model obtained in the three-dimensional model obtaining step.

Contour lines can also be used to calculate the highest point and the lowest point based on the three-dimensional model. For example, the calculation unit 10c obtains the height information of each point in the three-dimensional model and calculates a line connecting the points of the same height (i.e., a contour line). The calculation unit 10c calculates multiple contour lines at a contour interval entered through the input unit 10b. Each contour line is given the height information. Based on this height information, the calculation unit 10c calculates the highest point and the lowest point in the longitudinal direction.

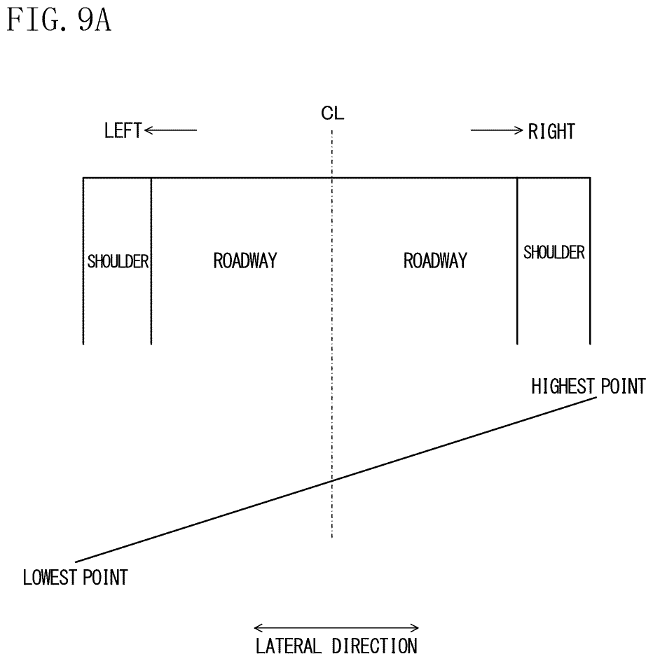

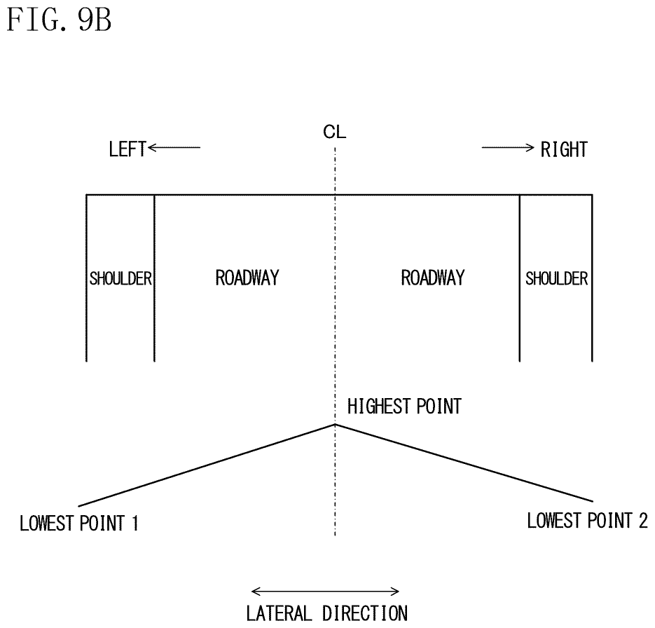

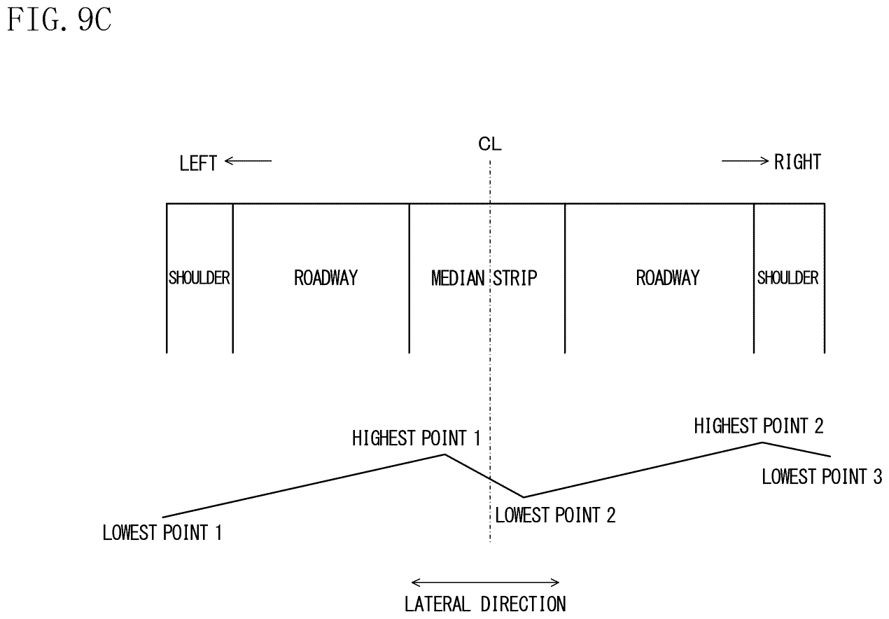

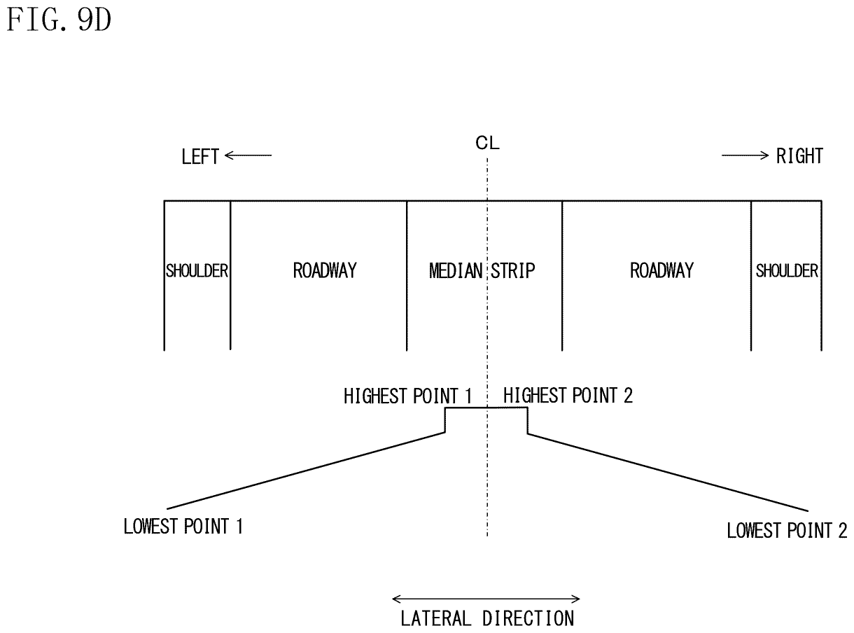

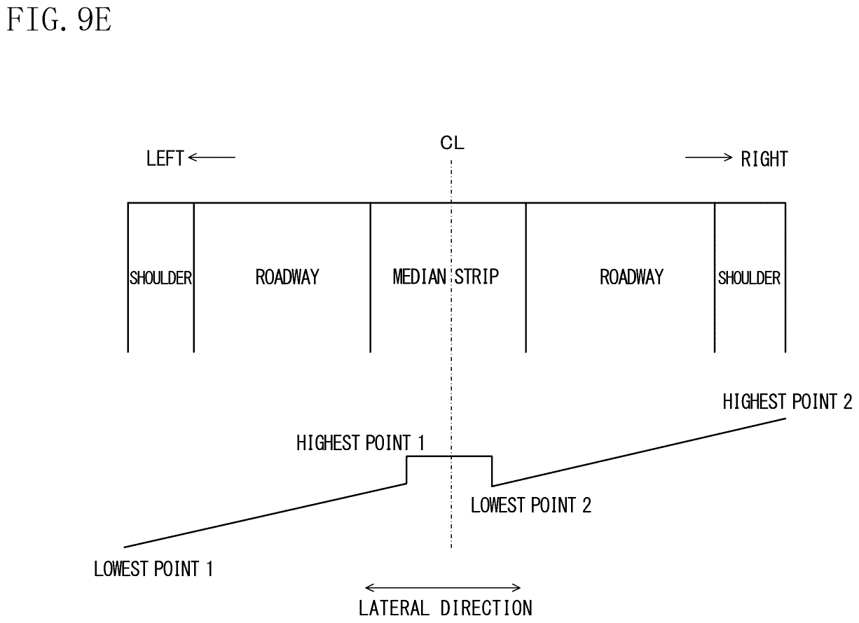

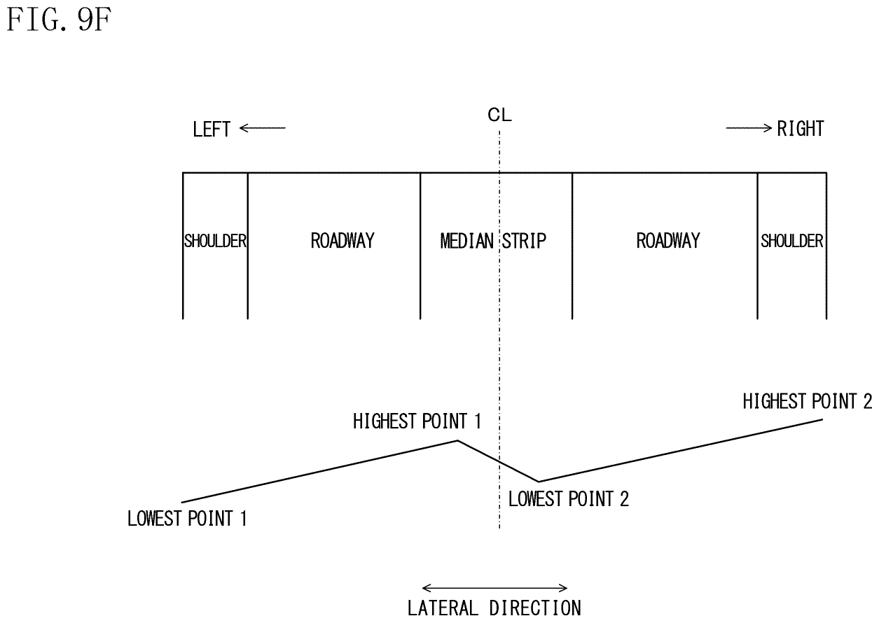

In step SA6, the calculation unit 10c calculates the highest point and the lowest point in the lateral direction of the three-dimensional model based on the multiple pieces of information obtained in steps SA3 and SA4. FIG. 9A of FIG. 9 illustrates a lateral cross-section including a roadway, a centerline (denoted by “CL”, the same applies hereafter), and both shoulders, in which the highest point is located at the edge of the right shoulder and the lowest point is located at the edge of the left shoulder. FIG. 9B illustrates a lateral cross-section including a roadway, a centerline, and both shoulders, in which the highest point is located on the centerline, the lowest point 1 is located at the edge of the left shoulder, and the lowest point 2 is located at the edge of the right shoulder. The example illustrated in FIG. 9B includes two lowest points for one highest point.

FIG. 9C illustrates a lateral cross-section including a roadway and a median strip, a centerline, and both shoulders, in which the highest point 1 is located to the left of the centerline in the median strip, and the lowest point 1 paired with the highest point 1 is located at the edge of the left shoulder. The lowest point 2 is located to the right of the centerline in the median strip. Further, the highest point 2 is located in the right shoulder closer to the roadway, and the lowest point 3 is located at the edge of the right shoulder.

In FIG. 9D, the highest point 1 is located to the left of the centerline in the median strip, and the lowest point 1 paired with the highest point 1 is located at the edge of the left shoulder. Further, the highest point 2 is located to the right of the centerline in the median strip, and the lowest point 2 paired with the highest point 2 is located at the edge of the right shoulder. The highest point 1 and the highest point 2 are at the same height.

In FIG. 9E, the highest point 1 is located to the left of the centerline in the median strip, and the lowest point 1 paired with the highest point 1 is located at the edge of the left shoulder. The highest point 2 is located at the edge of the right shoulder, and the lowest point 2 paired with the highest point 2 is located to the right of the centerline in the median strip. The highest point 2 is set higher than the highest point 1, and the highest point 1 and the lowest point 2 are at the same height.

In FIG. 9F, the highest point 1 is located to the left of the centerline in the median strip, and the lowest point 1 paired with the highest point 1 is located at the edge of the left shoulder. The highest point 2 is located at the edge of the right shoulder, and the lowest point 2 paired with the highest point 2 is located to the right of the centerline in the median strip. The highest point 2 is set higher than the highest point 1, and the lowest point 2 is set lower than the highest point 1.

When calculating the highest point and the lowest point in the lateral direction of the three-dimensional model, the height information of each point is calculated from the multiple pieces of information obtained in steps SA3 and SA4, similarly to the case of the longitudinal direction. Based on this height information calculated, it is possible to calculate a highest point position and a lowest point position (measurement points). Contour lines can also be used to calculate the highest point and the lowest point in the lateral direction, similarly to the case of the longitudinal direction. That is, each contour line is given the height information. Based on this height information, the calculation unit 10c calculates the highest point and the lowest point in the lateral direction.

The calculation unit 10c can perform steps SA5 and SA6 and calculate a combined gradient consisting of a gradient in the longitudinal direction and a gradient in the lateral direction. Specifically, the calculation unit 10c calculates a combined gradient by combining a gradient and a cross slope. The road surface has a gradient and a cross slope, and the steepest gradient is greater than both the gradient and the cross slope. The steepest gradient is called a combined gradient. The direction of the combined gradient is the direction of a stream line. The formula for calculating the combined gradient is generally known; therefore, the description thereof is omitted here.

In step SA7, the area generation unit 10d generates multiple areas by automatically dividing the rainwater catchment area in the three-dimensional model in a range from the highest point to the lowest point calculated by the calculation unit 10c, based on the design information owned by the user. In this case, the calculation unit 10c uses the highest point and the lowest point calculated based on the combined gradient.

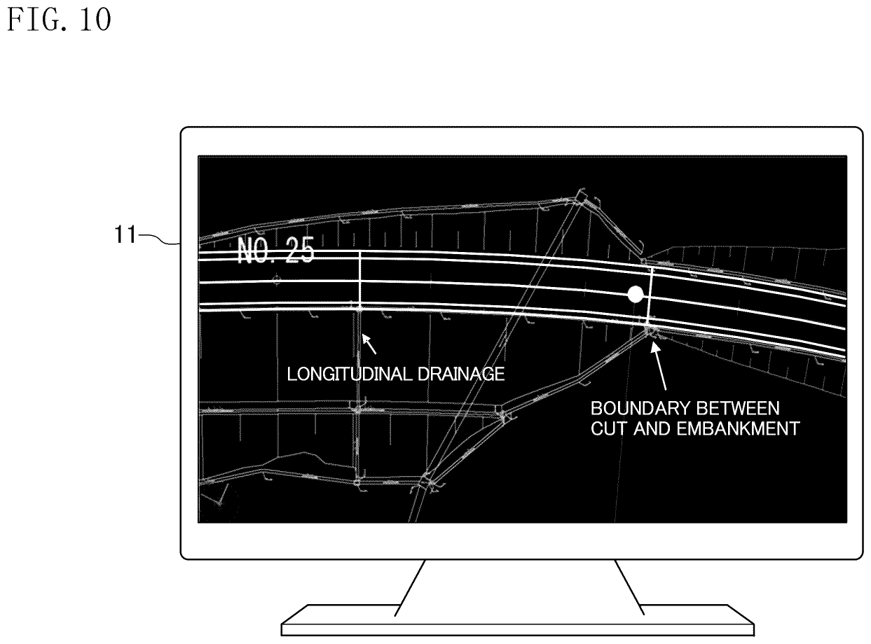

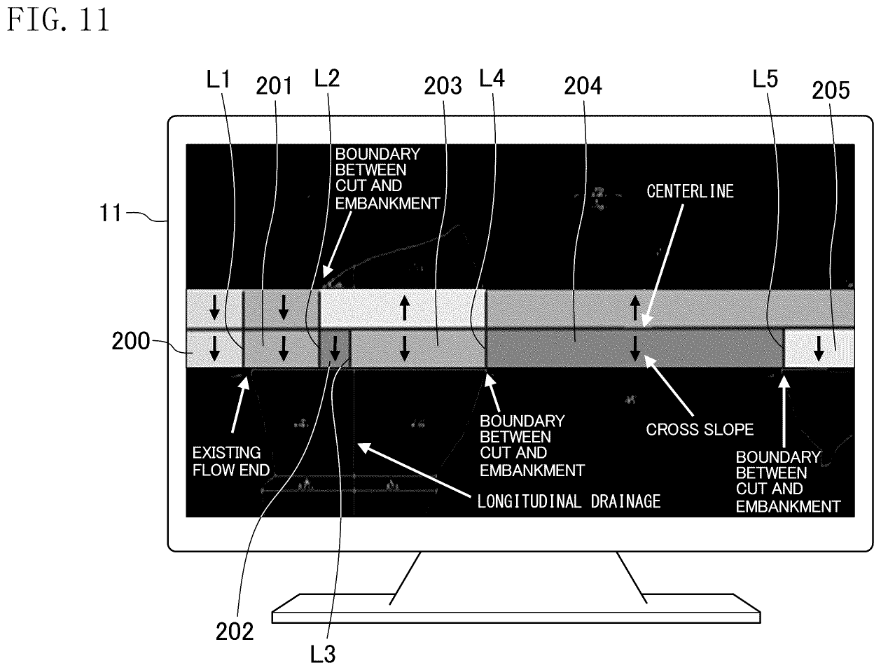

Specifically, as illustrated in FIG. 10, the control unit 10A can display, on the three-dimensional model, information on a longitudinal drainage and information on a boundary between cut and embankment as the design information. FIG. 11 is an example of the display 11 displaying a state in which the drainage area is divided into areas, starting from the highest point of the combined gradient to the lowest point, based on design information such as information on an existing flow end, information on a boundary between cut and embankment, and information on a longitudinal drainage. In FIG. 11, lines L1, L2, L3, L4, and L5 dividing the drainage area extend in the vertical direction of FIG. 11. The line L1 is located at a portion corresponding to an existing flow end. The lines L2, L4, and L5 are located at portions each corresponding to a boundary between cut and embankment. The line L3 is located at a portion corresponding to the longitudinal drainage. The multiple areas 200, 201, 202, 203, 204, and 205 are formed by dividing the drainage area with lines L1, L2, L3, L4, and L5. In this example, multiple areas 200, 201, 202, 203, 204, and 205 are divided in the longitudinal direction.

In step SA8, the area generation unit 10d generates multiple smaller areas by dividing, in the lateral direction (lateral direction of the roadway), each of the areas generated by the division in the longitudinal direction in step SA7, according to a predetermined attribute. Each area generated in step SA8 is given the identification information and temporarily stored in storage 13 or the like in association with area specifying information.

In making the division in the lateral direction, the area generation unit 10d can divide the multiple areas divided in the longitudinal direction, according to a road width attribute. The width attribute can be obtained in step SA4 and includes information such as the median strip (central reservation), the roadway, shoulder, and the like. Specifically, it is assumed that when the left-right direction (lateral direction) is defined as illustrated in FIG. 11, the embankment 102 and the cut 103 are located on both the left and right sides, with the left and right shoulders 120 and the left and right roadways 121 located therebetween. The widths of the shoulders 120 and the roadways 121 and the location of the centerline are included in the width attribute. In this case, the area generation unit 10d generates a plurality of dividing lines 130 generated by the division in the longitudinal direction and arranged in the longitudinal direction. Each of the dividing lines 130 is the normal to the road centerline and extends in the lateral direction. Steps SA7 and SA8 are area generation steps for generating multiple areas by automatically dividing the three-dimensional model in a range between the highest point and the lowest point calculated in the calculation step, based on the design information owned by the user.

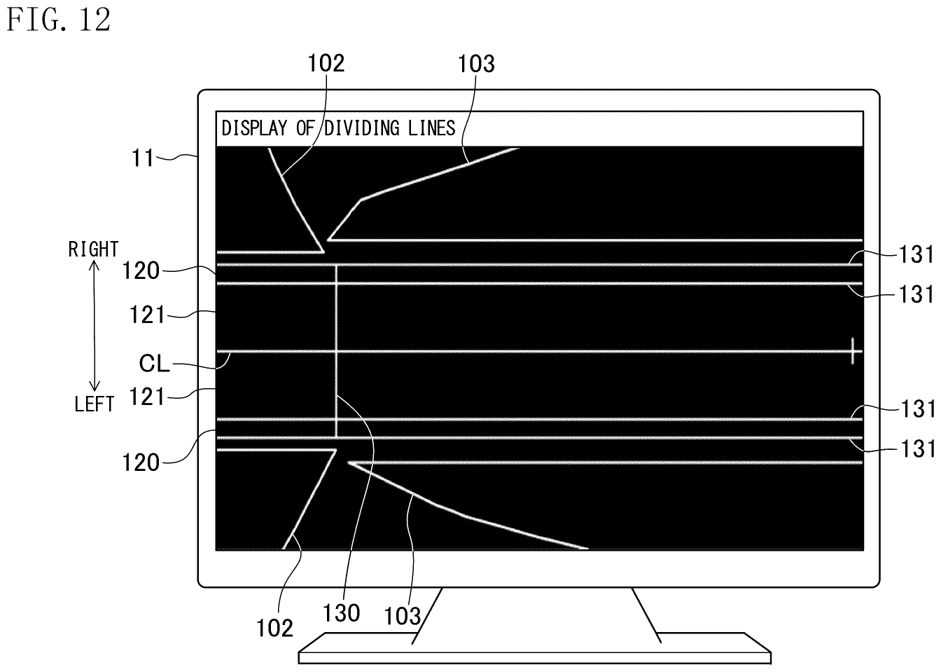

The area generation unit 10d generates a plurality of dividing lines 131 arranged in the lateral direction by dividing the area in the lateral direction based on a width attribute. In the example illustrated in FIG. 12, the dividing lines 130 extending in the lateral direction are positioned on the boundary between the shoulder 120 and the roadway 121 and on the centerline CL. The arrows on the roadways in FIG. 12 indicate the directions of the cross slopes. It is possible to indicate the cross slope of each area in this manner. The area generation unit 10d may also divide the multiple areas divided in the longitudinal direction into even smaller areas from the highest point in the lateral direction to the lowest point in the lateral direction.

In step SA9, the output unit 10e obtains the area specifying information which specifies areas divided in step SA8 and the area number. The output unit 10e also calculates the size of the area specified by the area specifying information. The size of the area can be calculated using the area calculation functions of conventional three-dimensional CAD software or the like. In other words, the catchment area of each area at a time when rainwater flows through the area generated by the area generation unit 10d can be obtained automatically. The output unit 10e outputs the area obtained through the calculation to the display 11 as the catchment area of the area. This is referred to as an output step for outputting the area of the area obtained through the calculation, as the catchment area of the area. In addition to the catchment area, the display 11 shows the shape of the area generated by the area generation unit 10d and the rainwater runoff as well.

The output unit 10e calculates the rainwater runoff by using the catchment area. The formula for calculating the rainwater runoff amount (Q) is well known and can be calculated using the runoff coefficient, the average rainfall intensity (mm/hour) within a time of concentration (t), and the catchment area (ha). Standard runoff coefficients corresponding to each surface type may be used as the runoff coefficient. The average rainfall intensity can be calculated using a rainfall intensity formula set for each region. The time of concentration can be a combination of an inlet time (minutes) and a flow time (minutes). The flow time can be calculated using the length of flow (m) and the average flow rate (m/sec).

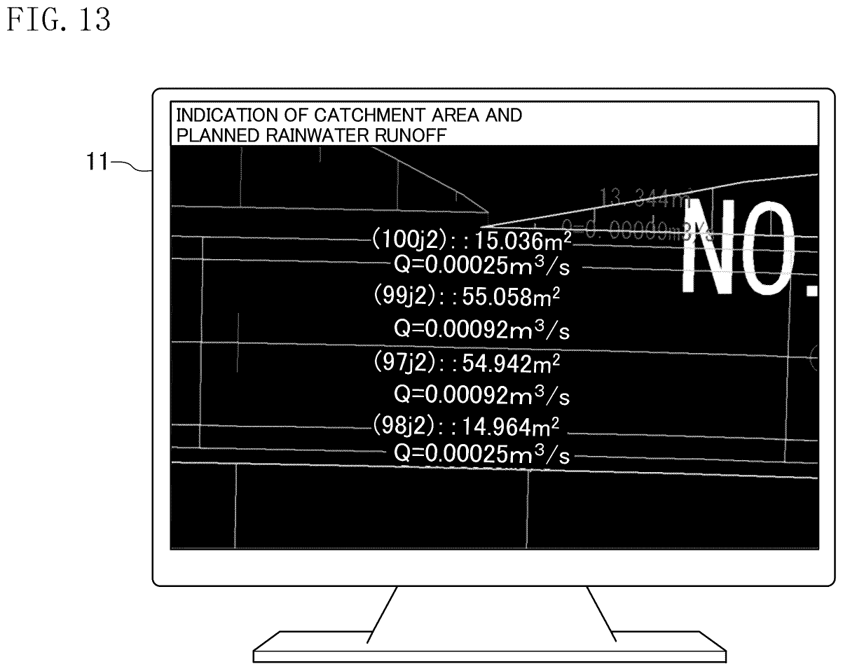

After obtaining the area specifying information, the area number, the catchment area, and the runoff amount, the output unit 10e generates CAD data or image data that is displayable on the display 11 and outputs the same to the display 11 (step SA11). As illustrated in FIG. 13, the display 11 shows the area number within each area, along with the catchment area and runoff amount of that area specified by the area number. For example, areas are divided by white lines, and the area numbers assigned to the respective areas are “100j2,” “99j2,” “97j2,” and “98j2.” The catchment area of the area number “100j2”, for example, is 15.036 m² and the runoff amount (Q) is 0.00025 m³/s. The catchment area and the runoff amount for each area can be indicated in this manner, which allows the user to grasp the catchment area and the runoff amount accurately.

After step SA9, the process may proceed to step SA10 without proceeding to step SA11. After step SA9, the user can select whether to proceed to step SA11 or step SA10. If step SA10 is selected, the flow direction of each area is calculated. Specifically, the output unit 10e calculates the highest point and the lowest point of each area generated in step SA8. This calculation can be made based on the height information included in the three-dimensional model. The output unit 10e calculates the highest point and the lowest point of each area, and then generates high/low information to indicate the relatively lower part of the area based on the highest point and the lowest point of each area. An example of the high/low information is an arrow pointing from a relatively higher part to a lower part, but the high/low information is not limited to such an arrow.

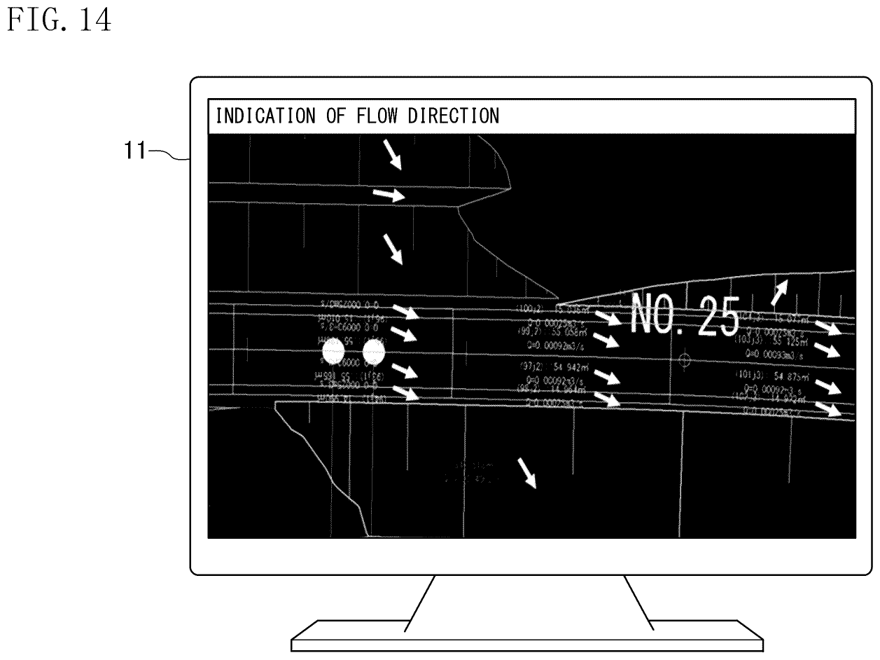

After obtaining the high/low information, the output unit 10e generates CAD data or image data that is displayable on the display 11 and outputs the same to the display 11 (step SA11). As illustrated in FIG. 14, the display 11 shows an arrow pointing from a relatively higher part to a lower part within each area. As an example, the areas are divided by white lines, and a single arrow is displayed in each area. It is thus possible to display the flow direction for each area.

If the determination is NO in step SA2, it means that there is no design information in the three-dimensional model, and such three-dimensional models include, for example, housing sites, developed sites, parking lots, or the like. If the determination is NO in step SA2, the process proceeds to step SB1 of the flowchart in FIG. 15. In step SB1, the calculation unit 10c creates contour lines. Specifically, the calculation unit 10c first reads the three-dimensional model obtained by the three-dimensional model obtaining unit 10a. Since the three-dimensional model includes height information of each point in the model, the calculation unit 10c obtains the height information of each point and calculates a line connecting the points of the same height, i.e., a contour line. If the creation intervals of the contour lines have been input through the input unit 10b, the calculation unit 10c calculates the contour lines at the intervals input through the input unit 10b. Since the contour lines are calculated at the predetermined intervals, a plurality of lines are calculated. Each contour line is given the height information. The display 11 can display the height information of each contour line in the form of numerical value on the three-dimensional model shown on the display 11, as the height of the contour line, along with the contour line.

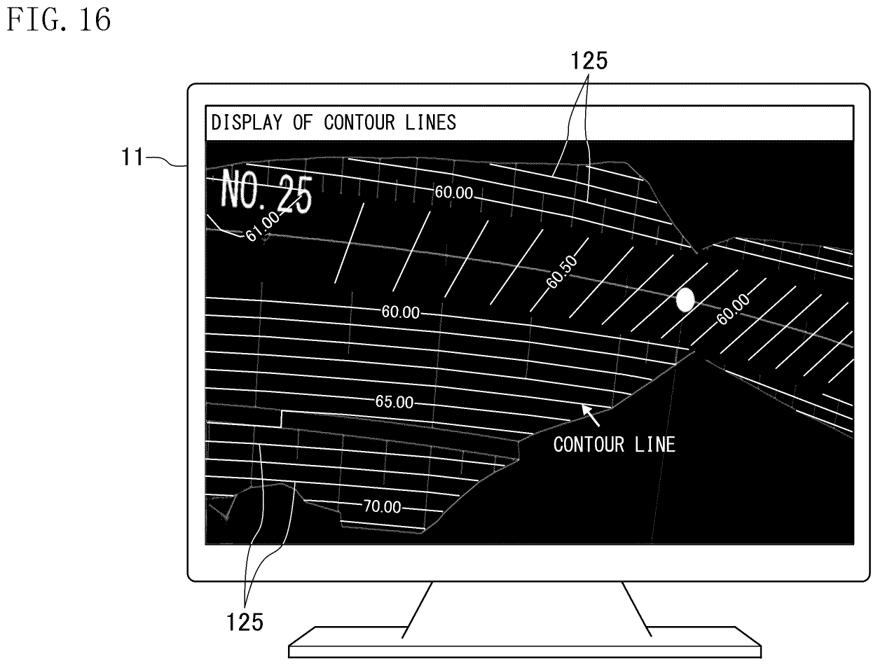

FIG. 16 illustrates an example in which a plurality of contour lines 125 calculated by the calculation unit 10c are superimposed on the three-dimensional model shown in the three-dimensional polygonal display mode. The image shown in the figure is an example, and the actual shape of the contour lines can be complex, and the density of the contour lines 125 is higher if the gradient is steeper or lower if the gradient is gentler. The density of the contour lines 125 can be expressed as the number of contour lines 125 per unit area.

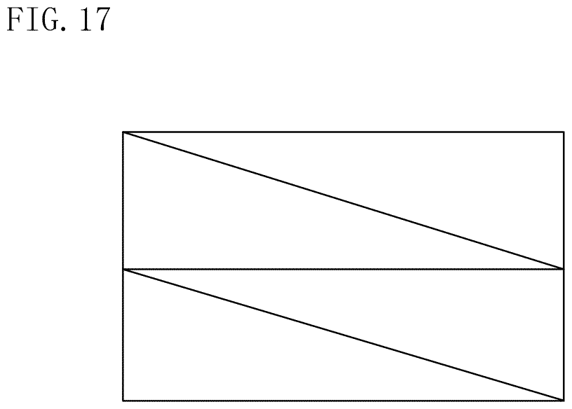

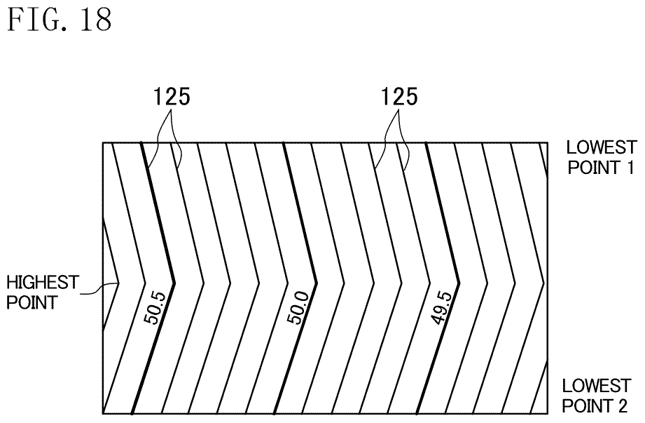

FIG. 17 illustrates a planned three-dimensional model of a housing site, a developed site, a parking lot, or the like. FIG. 18 illustrates contour lines superimposed on the planned three-dimensional model in FIG. 17.

In step SB2, the calculation unit 10c compares the heights of adjacent contour lines to detect the highest point and the lowest point. That is, the calculation unit 10c is a unit that determines the high/low relationship between the adjacent contour lines 125 out of the plurality of contour lines 125, and first selects two adjacent contour lines 125 arbitrarily. The calculation unit 10c determines which of the two contour lines 125 selected is higher or lower based on the height information given to each of the two contour lines 125. After the determination on the pair, the high/low relationship of another adjacent contour lines 125 is determined in the same manner. By repeating this process, the high/low relationships of all contour lines 125 illustrated in FIG. 18 can be determined. The determination result of the high/low relationship is temporarily stored in the storage 13. The determination method described above is an example, and the high/low relationship of adjacent contour lines 125 may be determined through another method. After the high/low relationships of all contour lines 125 are determined, the calculation unit 10c sets a point on the highest contour line 125 as the highest point and a point on the lowest contour line 125 as the lowest point. FIG. 18 illustrates an example in which the lowest point 1 and the lowest point 2 are detected.

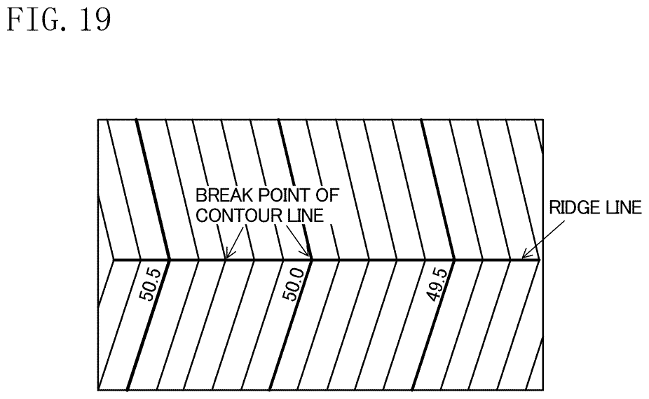

In step SB3, the area generation unit 10d detects break points of the contour lines and calculates lines (ridge lines or valley lines) connecting the break points (see FIG. 19). The calculated ridge lines or valley lines serve as divider lines that divide an area from another.

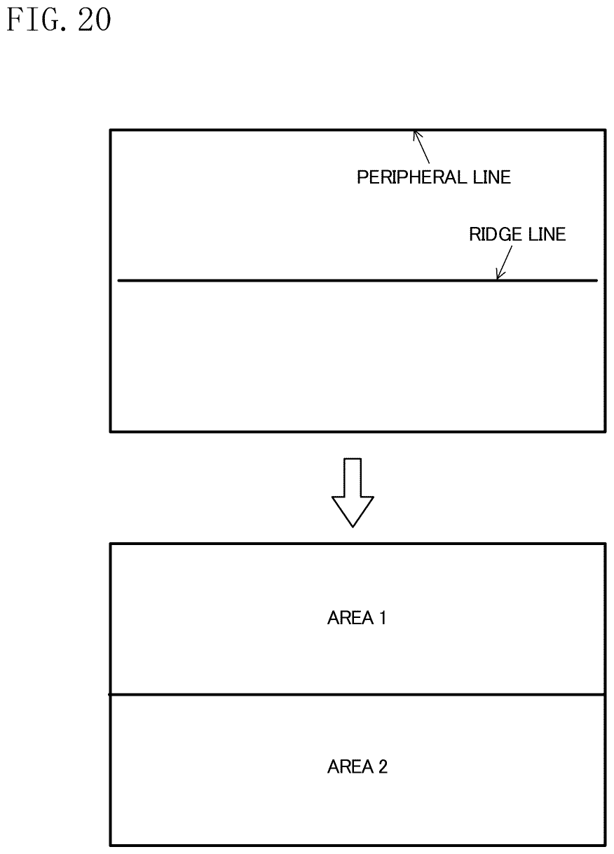

In step SB4, the area generation unit 10d divides the planned three-dimensional model into multiple areas by using the ridge lines or valley lines calculated in step SB3 as divider lines (see FIG. 20). The area numbers (such as AREA 1 and AREA 2) are temporarily stored in the storage 13 or the like, in association with the area specifying information. The planned three-dimensional model may be divided into multiple areas through a manual input by the user.

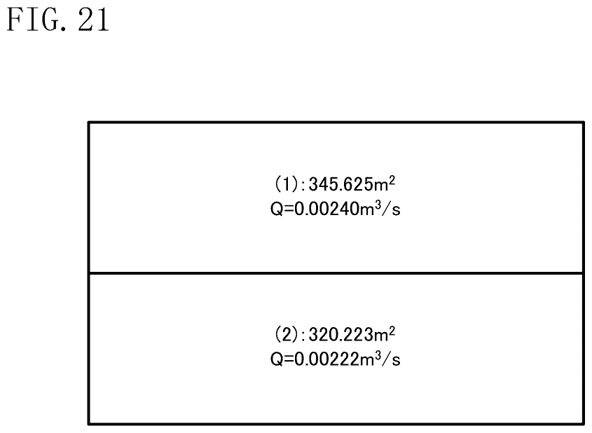

In step SB5, the output unit 10e obtains the catchment area, the height difference, and the runoff amount (Q) of each area. The height difference of each area can be obtained based on the information of the contour lines. After obtaining the area specifying information, the area number, the catchment area, and the runoff amount, the output unit 10e generates image data that is displayable on the display 11 and outputs the same to the display 11 (step SB7). As illustrated in FIG. 21, the display 11 shows the area number within each area, along with the catchment area and runoff amount of that area specified by the area number.

After step SB5, the process may proceed to step SB6 without proceeding to step SB7. After step SB5, the user can select whether to proceed to step SB7 or step SB6. If step SB6 is selected, the flow direction of each area is calculated. Specifically, the output unit 10e calculates the highest point and the lowest point of each area divided in step SB4. These can be obtained through calculation based on the contour line information. The output unit 10e calculates the highest point and the lowest point of each area, and then generates high/low information to indicate the relatively lower part of the area based on the highest point and the lowest point of each area. An example of the high/low information is an arrow pointing from a relatively higher part to a lower part.

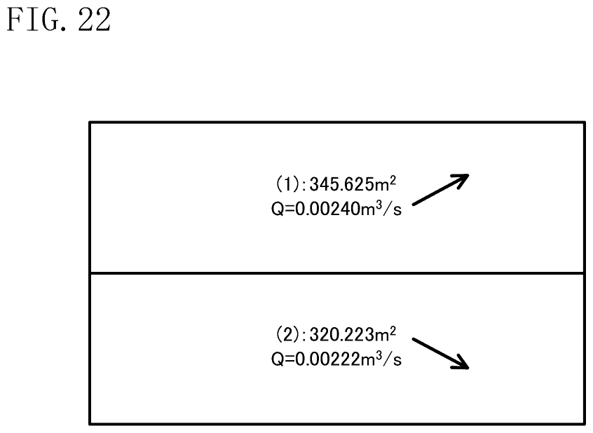

After obtaining the high/low information, the output unit 10e generates image data that is displayable on the display 11 and outputs the same to the display 11 (step SB7). As illustrated in FIG. 22, the display 11 shows an arrow pointing from a relatively higher part to a lower part within each area.

### Advantages of Embodiment

As described above, according to the present embodiment, the three-dimensional model obtaining unit 10a obtains a three-dimensional model representing the current topography and a planning model. Since the three-dimensional model obtained includes height information, the calculation unit 10c can calculate the highest point and the lowest point on the three-dimensional model based on the height information of the three-dimensional model. The area generation unit 10d generates multiple areas by automatically dividing the rainwater catchment area in the three-dimensional model in a range starting from the highest point to the lowest point on the three-dimensional model, based on the design information owned by the user.

The output unit 10e calculates the area of each of the multiple areas generated by the above process. The area obtained by the calculation is output as the catchment area of the area. Since it is also possible to obtain the rainwater runoff through calculation based on the catchment area, the user can accurately and quickly grasp the catchment area and the runoff amount of each area by simply entering the three-dimensional model, the design information, and the like.

The above-described embodiments are merely examples in all respects and should not be interpreted as limiting. All modifications and changes belonging to the equivalent scope of the claims are included in the scope of the present invention.

As described above, the automatic calculation device and automatic calculation program according to the present invention can be used for various types of designs, such as designs for roads, house pads, residential land development, rivers, parking lots, and harbor facilities.

### DESCRIPTION OF REFERENCE CHARACTERS

1 Automatic Calculation Device for Catchment Area
10a Three-Dimensional Model Obtaining Unit
10b Input Unit
10c Calculation Unit
10d Area Generation Unit
10e Output Unit
11 Display

What is claimed is:

1. An automatic calculation device configured to automatically calculate rainwater runoff of a predetermined area on a three-dimensional model representing a current topography and a planning model, the automatic calculation device comprising:
a three-dimensional model obtaining unit configured to obtain the three-dimensional model;
a calculation unit configured to calculate a highest point and a lowest point based on the three-dimensional model obtained by the three-dimensional model obtaining unit;
an area generation unit configured to generate multiple areas by automatically dividing a rainwater catchment area in the three-dimensional model in a range from the highest point to the lowest point calculated by the calculation unit, based on design information owned by a user; and
an output unit configured to calculate an area of each of the areas generated by the area generation unit and output the area obtained by the calculation, and calculate and output rainwater runoff by using the area obtained by the calculation.

2. The automatic calculation device of claim 1, wherein
the design information includes any one or more of information on an existing flow end, information on a boundary between cut and embankment, and information on a longitudinal drainage.

3. The automatic calculation device of claim 1, wherein
the calculation unit calculates the highest point and the lowest point based on a combined gradient consisting of a gradient in a longitudinal direction and a gradient in a lateral direction.

4. The automatic calculation device of claim 1, wherein
the area generation unit generates the multiple areas by dividing the rainwater catchment area in the three-dimensional model in a lateral direction of a roadway according to a predetermined attribute.

5. The automatic calculation device of claim 1, further comprising:
a display configured to display the areas generated by the area generation unit and the area output from the output unit.

6. The automatic calculation device of claim 5, wherein
the display shows the rainwater runoff output from the output unit.

7. The automatic calculation device of claim 5, wherein
the output unit calculates the highest point and the lowest point of each of the areas and generates and outputs high/low information indicating a relatively lower part of the area based on the highest point and the lowest point of each of the areas, and
the display shows an arrow based on the high/low information output from the output unit, along with the three-dimensional model.

8. The automatic calculation device of claim 7, wherein
the display shows a high/low indication indicating a relatively lower part based on the high/low information output from the output unit, along with the three-dimensional model.

9. The automatic calculation device of claim 5, wherein
the calculation unit calculates a path extension and a gradient between the highest point and the lowest point, and
the display shows the path extension and the gradient between the highest point and the lowest point.

10. An automatic calculation program configured to automatically calculate rainwater runoff of a predetermined area on a three-dimensional model representing a current topography and a planning model, the automatic calculation program causing a computer to execute:
a three-dimensional model obtaining step of obtaining the three-dimensional model;
a calculation step of calculating a highest point and a lowest point based on the three-dimensional model obtained in the three-dimensional model obtaining step;
an area generation step of generating multiple areas by automatically dividing a rainwater catchment area in the three-dimensional model in a range from the highest point to the lowest point calculated in the calculation step, based on design information owned by a user; and
an output step of calculating an area of each of the areas generated in the area generation step and outputting the area obtained by the calculation, and calculating and outputting rainwater runoff by using the area obtained by the calculation.
